(19) United States
(12) Patent Application Publication
(10) Pub. No.: US 2024/0196633 A1
(43) Pub. Date: Jun. 13, 2024

(54) MEMORY DEVICE AND SYSTEM HAVING MULTIPLE PHYSICAL INTERFACES

(71) Applicant: Samsung Electronics Co., Ltd., Suwon-si (KR)

(72) Inventors: Yunseok Yang, Suwon-si (KR); Seula Ryu, Suwon-si (KR); Jaewoo Shin, Suwon-si (KR); Minhwan An, Suwon-si (KR); Seongjin Lee, Suwon-si (KR); Sunghak Lee, Suwon-si (KR); Eungchang Lee, Suwon-si (KR); Yunkyeong Jeong, Suwon-si (KR); Jinsuk Chung, Suwon-si (KR)

(21) Appl. No.: 18/529,365

(22) Filed: Dec. 5, 2023

(30) Foreign Application Priority Data
Dec. 7, 2022 (KR) 10-2022-0170062
Jun. 23, 2023 (KR) 10-2023-0081335

(51) Int. Cl. H10B 80/00; H01L 25/065; H01L 25/18

(52) U.S. Cl. CPC H10B 80/00; H01L 25/0652; H01L 25/18; H01L 2225/06513; H01L 2225/06541; H01L 2225/06586

(57) ABSTRACT

A memory device and a system includes a plurality of physical interfaces. The memory device includes a buffer die including a first interface circuit and a second interface circuit configured to communicate with an external device and a memory die stack mounted on the buffer die and including a plurality of stacked memory dies. The plurality of memory dies are electrically connected to the first interface circuit and the second interface circuit, the first interface circuit is configured to activate responsive to a first selection signal, and the second interface circuit is configured to activate responsive to a second selection signal. The first selection signal and the second selection signal are received from a memory controller external to the memory device.

### CROSS-REFERENCE TO RELATED APPLICATION

This application is based on and claims priority under 35 U.S.C. § 119 to Korean Patent Application Nos. 10-2022-0170062, filed on Dec. 7, 2022, and 10-2023-0081335, filed on Jun. 23, 2023, in the Korean Intellectual Property Office, the disclosures of which are incorporated by reference herein in their entirety.

### BACKGROUND

The inventive concept relates to a semiconductor device, and more particularly, to a memory device and system that selectively uses some physical interfaces in a memory device constituting a plurality of physical interfaces.

Applications like high performance and/or graphics algorithms are data-intensive and compute-intensive. Machine learning applications, such as neural networks, may include a large number of operations including a large amount of computations and memory requirements. Machine learning applications may require a computing system with large computational and memory capabilities to more accurately train or learn different data sets.

A high bandwidth memory (HBM) is a high-performance RAM interface for 3-dimensionally stacked dynamic random access memories (DRAM). An HBM may be used for memory-centric and heavy computation neural networks or other artificial intelligences (AI). An HBM provides wide input/output in the form of a multi-channel interface and may include a physical interface (hereinafter referred to as “PHY”) used for communication with a memory controller of a host using the HBM. The memory controller may also include a PHY used for communication with the HBM, wherein the PHY of the memory controller corresponds to the PHY of the HBM on the one-on-one basis.

An HBM may perform high-capacity memory operations demanded by applications and may include multiple PHYs to support the high-capacity memory operations. Correspondingly, the number of PHYs in the memory controller may also increase, and thus the chip area of the memory controller may increase.

### SUMMARY

Embodiments of inventive concept may provide a memory device and a system that selectively utilizes a plurality of physical interfaces included in the memory device without increasing the chip area of a memory controller.

According to an aspect of the inventive concept, there is provided a memory device including a buffer die including a first interface circuit and a second interface circuit configured to communicate with an external device, wherein the first interface circuit is configured to activate responsive to a first selection signal, and the second interface circuit is configured to activate responsive to a second selection signal, and a memory die stack mounted on the buffer die and including a plurality of memory dies, wherein the plurality of memory dies are electrically connected to the first interface circuit and the second interface circuit, wherein the first selection signal and the second selection signal are received from a memory controller external to the memory device.

According to another aspect of the inventive concept, there is provided a memory device including a buffer die including a first interface circuit and a second interface circuit configured to communicate with an external device, wherein the first interface circuit is configured to activate responsive to a first selection signal, and the second interface circuit is configured to activate responsive to a second selection signal, and a memory die stack mounted on the buffer die and including a plurality of memory dies, wherein the plurality of memory dies are electrically connected to the first interface circuit and the second interface circuit, wherein, which of the first interface circuit and the second interface circuit is activated to communicate with an external memory controller is based on whether the first selection signal is fixed to a first voltage level or a second voltage level different from the first voltage level and whether the second selection signal is fixed to the first voltage level or the second voltage level.

According to another aspect of the inventive concept, there is provided a memory device including a buffer die including a first interface circuit and a second interface circuit configured to communicate with an external device, wherein the first interface circuit is configured to activate responsive to a first selection signal, and the second interface circuit is configured to activate responsive to a second selection signal, and a memory die stack mounted on the buffer die and including a plurality of memory dies, wherein the plurality of memory dies are electrically connected to the first interface circuit and the second interface circuit, wherein the first selection signal and the second selection signal are generated inside the memory device responsive to an interface selection signal received from a memory controller external to the memory device.

### BRIEF DESCRIPTION OF THE DRAWINGS

Embodiments of the inventive concept will be more clearly understood from the following detailed description taken in conjunction with the accompanying drawings in which:

FIGS. 1A and 1B are block diagrams that illustrate a system according to embodiments;

FIGS. 2A and 2B are diagrams that illustrate a system including a memory device according to embodiments;

FIG. 3 is a diagram that illustrates the operation of two HBM PHYs of FIG. 2A, that is, a first high bandwidth memory (HBM) physical interface (PHY) and a second HBM PHY;

FIG. 4 is a diagram that illustrates a memory device according to embodiments;

FIG. 5 is a diagram that illustrates a portion of a semiconductor package implementing a system according to embodiments;

FIGS. 6 and 7 are timing diagrams that illustrate a read operation of a memory device according to embodiments;

FIGS. 8, 9a and 9B are diagrams that illustrate a memory device according to embodiments;

FIGS. 10, 11a and 11B are diagrams that illustrate a memory device according to embodiments;

FIG. 12 is a diagram that illustrates a memory device according to embodiments;

FIG. 13 is a flowchart that illustrates the operation of a memory device according to embodiments; and

FIG. 14 is a block diagram of a system that illustrates an electronic device including a memory device according to embodiments.

### DETAILED DESCRIPTION OF THE EMBODIMENTS

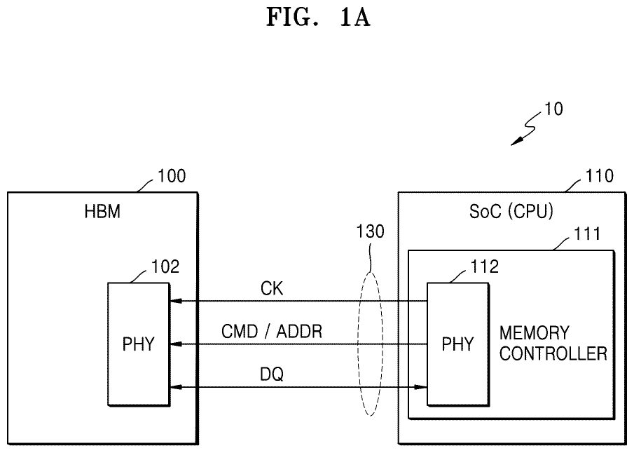

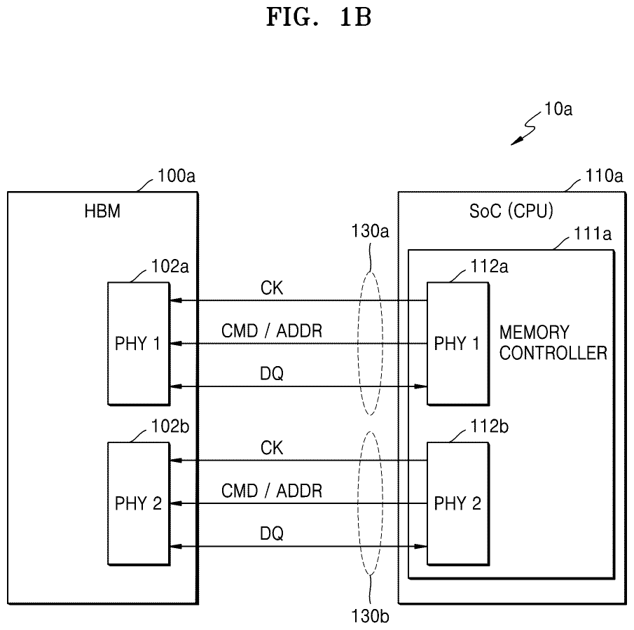

FIGS. 1A and 1B are block diagrams for describing a system according to embodiments. Hereinafter, subscripts attached to the same reference numerals in different drawings (e.g., a of 100a, a of 102a, and b of 102b) are used to distinguish a plurality of circuits that perform similar or identical functions. Hereinafter, embodiments will be described in detail with reference to the accompanying drawings. In this description, like reference numerals may indicate like components. It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

Referring to FIG. 1A, a system 10 may include a system-on-chip (SoC) 110 and a memory device 100. The SoC 110 is a functional block that performs computer operations within the system 10 and may correspond to a central processing unit (CPU), a graphics processing unit (GPU), a digital signal processor (DSP), or an application processor (AP). In this specification, the SoC 110 may be referred to as a CPU 110.

The CPU 110 may be configured to execute instructions, software, firmware, or pieces of combinations thereof that may be executed by one or more machines. The CPU 110 may include any number of processor cores. For example, the CPU 110 may include a single-core or a multi-core like dual-core, quad-core, and hexa-core.

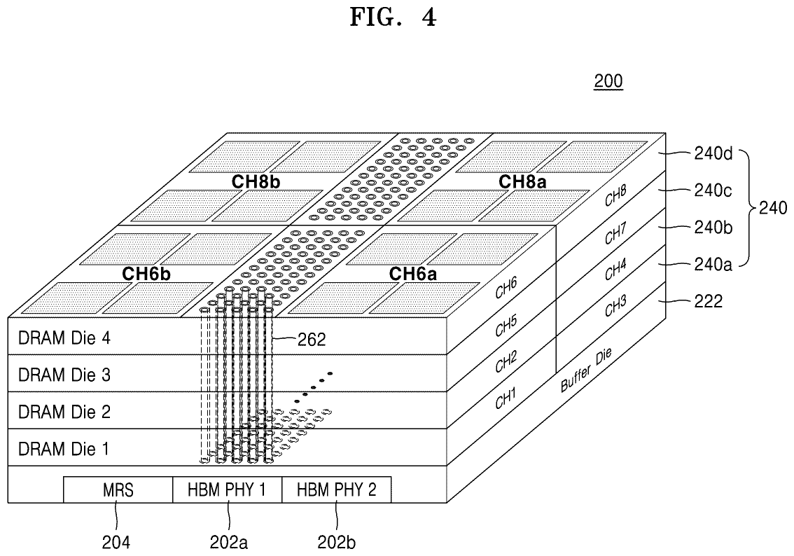

The memory device 100 may be a high bandwidth memory (HBM) including a plurality of stacked memory dies 240 (FIG. 4). The HBM may include a plurality of channels CH1 to CH8 (FIG. 4) having interfaces independent from one another. Hereinafter, for convenience of explanation, the terms memory device 100 and an HBM 100 may be used interchangeably. When each of the channels CH1 to CH8 has a bandwidth of 128 bits, the HBM 100 may include components for inputting/outputting data of 1024 bits. The HBM 100 may include an interface circuit 102 for performing data communication with the CPU 110. The interface circuit 102 may include a physical or electrical layer and a logical layer provided for signals, frequencies, timings, drivers, detailed operation parameters, and functionality needed for an efficient communication between the CPU 110 and the HBM 100. The interface circuit 102 may perform memory interfacing, such as selecting a row and a column corresponding to a memory cell, writing data to a memory cell, or reading written data. The interface circuit 102 may support features of the HBM protocol of the JEDEC standard. For example, the interface circuit 102 may perform 1024-bit data communication with the CPU 110. For convenience of explanation, the interface circuit 102 may be referred to as an HBM PHY, and the terms interface circuit 102 and an HBM PHY 102 may be used interchangeably.

The CPU 110 may include a memory controller 111 that controls the HBM 100. The memory controller 111 may include an interface circuit 112 for performing data communication with the HBM 100. The interface circuit 112 is connected to the HBM PHY 102 and may include a physical or electrical layer and a logical layer provided for signals, frequencies, timings, operation parameters, detailed operation parameters, and functionality needed for efficient communication between the CPU 110 and the HBM 100. The interface circuit 112 may perform memory interfacing, such as transmitting a memory cell address and write data to the HBM 100 and receiving read data output from the HBM 100. The interface circuit 112 may be referred to as a controller PHY 112, in correspondence to the term HBM PHY 102.

The controller PHY 112 may be coupled to a bus 130 that transfers a clock signal CK, a command/address CMD/ADDR, and data DQ to the channels CH1 to CH8 of the HBM 100. The controller PHY 112 and the HBM PHY 102 may communicate with each other through various buses. The clock signal CK may be provided between the memory controller 111 and the HBM 100 through a clock bus 130. The clock bus 130 may include signal lines for providing clock signals received by the HBM 100 (e.g., CK_t, CK_c, WDQS_t, and WDQS_c) and read clock signals (e.g., RDQS_t and RDQS_c) provided by the HBM 100 to the memory controller 111. The command/address CMD/ADDR is received by the HBM 100 on a command/address bus 130, and the data DQ is transmitted between the memory controller 111 and the HBM 100 through a DQ bus 130. Each bus 130 may include one or more signal lines on which signals are provided.

Clock signals CK_t and CK_c provided to the HBM 100 by the memory controller 111 are used for timing in the operations of providing and capturing the command/address CMD/ADDR, and clock signals WDQS_t and WDQS_c are used for timing in the operations of providing the data DQ. Clock signals RDQS_t and RDQS_c provided to the memory controller 111 by the HBM 100 are used for timing in the operations of providing the data DQ read from the HBM 100. The clock signals CK_t and CK_c clocks and the clock signals WDQS_t and WDQS_c are complementary with respect to each other, and the clock signals RDQS_t and RDQS_c are complementary with respect to each other. Clock signals are complementary with respect to each other when the rising edge of a first clock signal coincides with the falling edge of a second clock signal and the rising edge of the second clock signal coincides with the falling edge of the first clock signal. Hereinafter, for convenience of description, the clock signals CK_t and CK_c may be referred to as clock signals CK, the clock signals WDQS_t and WDQS_c may be referred to as clock signals WDQS, and the clock signals RDQS_t and RDQS_c may be referred to as clock signals RDQS.

When executing an application, the CPU 110 may need a large amount of computational capability and high memory capability to cooperatively execute jobs or tasks in parallel. The CPU 110 may allow overall jobs or tasks to be executed in parallel on the HBM PHY 102. In other words, the CPU 110 may use a parallel processing approach of dividing a job into smaller jobs by using a plurality of HBM PHYs 102a and 102b to solve an overall job or task, as shown in FIG. 1B. A task may include a plurality of jobs organized in a structure, such as a hierarchical structure, and the task may refer to executable code to be executed by a computing entity, data to be processed, and data to be retrieved from the HBM 100 by the computing entity, manipulated by executing code, and to be stored.

Referring to FIG. 1B, in a system 10a, an HBM 100a may include two HBM PHYs 102a and 102b, and the memory controller 111a may also include two controller PHYs 112a and 112b. The HBM PHYs 102a and 102b and the controller PHYs 112a and 112b may be connected to each other through buses 130a and 130b, respectively. A CPU 110a may control the HBM PHYS 102a and 102b to perform some of a plurality of computational jobs in the HBM 100a in parallel. However, the buses 130a and 130b and the controller PHYs 112a and 112b arranged in correspondence to the HBM PHYs 102a and 102b may be beneficial for processing jobs in parallel and/or increasing data bandwidth in the HBM 100a according to a request of the CPU 110a, but, in this case, the chip area of a memory controller 111a may be significantly increased.

Therefore, because the two HBM PHYs 102a and 102b may be selectively controlled by using one bus 130 and one controller PHY 112, a high-speed and high-performance solution for the CPU 110 may be provided without increasing the chip area of the memory controller 111a.

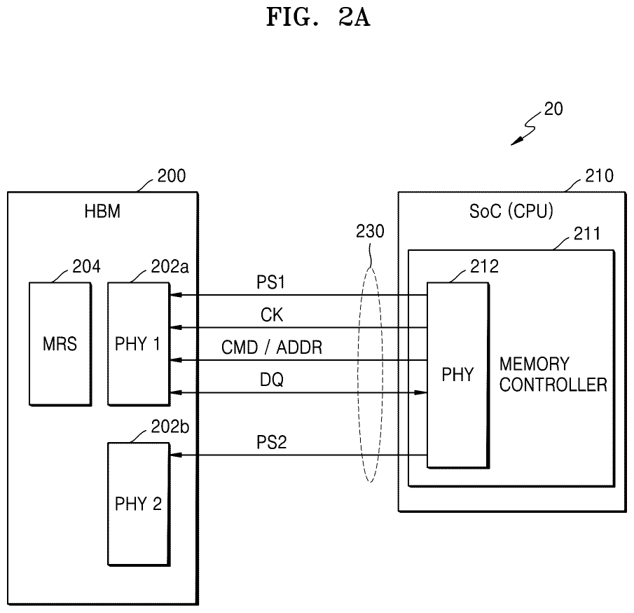

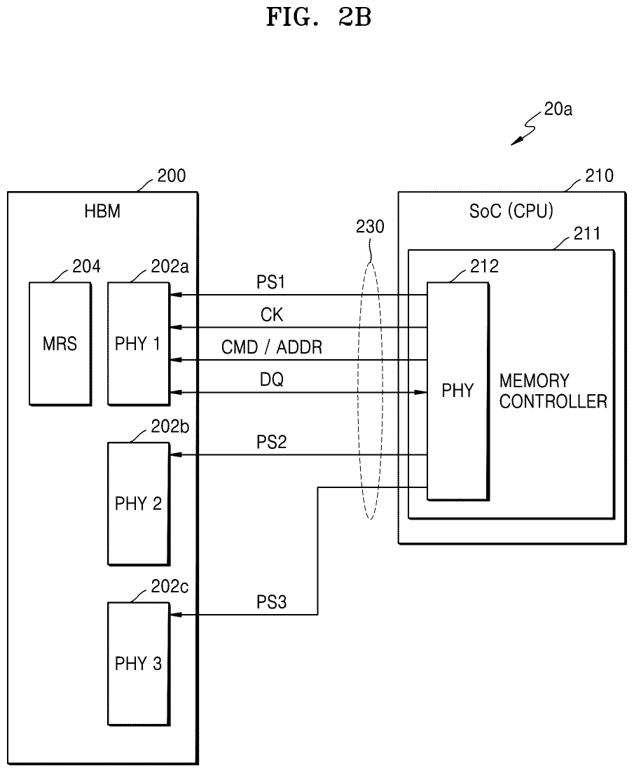

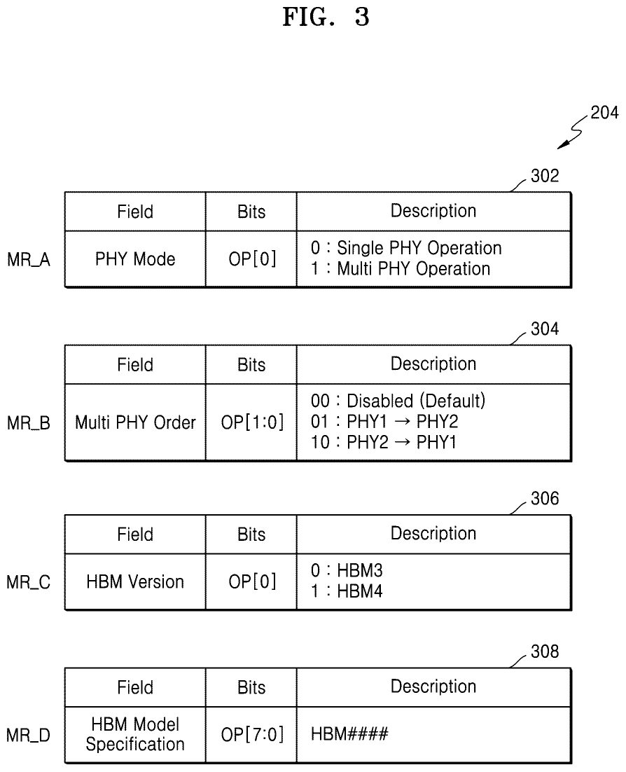

FIGS. 2A and 2B are diagrams that illustrate a system including a memory device according to embodiments. FIG. 3 is a diagram that illustrates the operation of two HBM PHYS of FIG. 2A, that is, a first HBM PHY 202a and a second HBM PHY 202b.

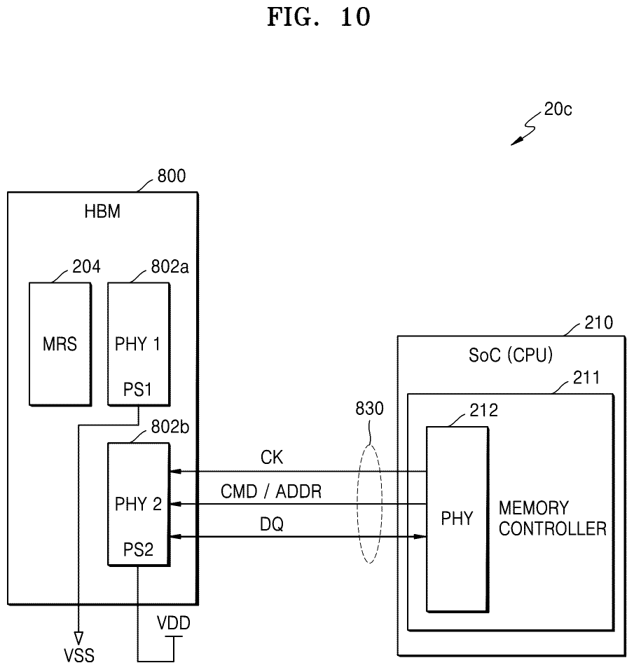

Referring to FIG. 2A, a system 20 may include a CPU 210 including an HBM 200 having the two HBM PHYs, that is, the first HBM PHY 202a and the second HBM PHY 202b, and a memory controller 211 having one controller PHY 212. The first HBM PHY 202a and the second HBM PHY 202b and the controller PHY 212 may be connected to each other through a bus 230 including a first selection signal PS1 and a second selection signal PS2. The clock signal CK, the command/address CMD/ADDR, and the data DQ shown on the bus 230 are signals transmitted to a single channel of the HBM 200 through the first HBM PHY 202a or the second HBM PHY 202b. Although the present embodiment illustrates an example in which the controller PHY 212 is connected to the first HBM PHY 202a, embodiments are not limited thereto, and the controller PHY 212 may also be connected to the second HBM PHY 202b (e.g., FIG. 10).

The first selection signal PS1 is provided from the controller PHY 212 to the first HBM PHY 202a and may serve as a signal to activate or deactivate the operation of the first HBM PHY 202a. The second selection signal PS2 is provided from the controller PHY 212 to the second HBM PHY 202b and may serve as a signal to activate or deactivate the operation of the second HBM PHY 202b. Activation or deactivation of each of the first HBM PHY 202a and the second HBM PHY 202b may be determined according to the logic level of each of the first selection signal PS1 and the second selection signal PS2. The different logic values may respectively correspond to different signal voltage levels. For example, when the first selection signal PS1 is at a logic high level, the first HBM PHY 202a may be activated, and, when the first selection signal PS1 is at a logic low level, the first HBM PHY 202a may be deactivated. When the second selection signal PS2 is at a logic high level, the second HBM PHY 202b may be activated, and, when the second selection signal PS2 is at a logic low level, the second HBM PHY 202b may be deactivated. The first selection signal PS1 and the second selection signal PS2 may each be received by the HBM 200 through an electrical connector (or a solder ball) of the HBM 200. The HBM 200 may activate or deactivate each of the first HBM PHY 202a and the second HBM PHY 202b according to the logic levels of the first selection signal PS1 and the second selection signal PS2, respectively.

The HBM 200 may include a mode register set (MRS) 204 that sets a plurality of operation options, various functions, characteristics, and modes of the HBM 200. The MRS 204 includes mode registers that store parameter codes for various operation parameters and control parameters and may be set up during initialization of the HBM 200 after the system 20 is powered up. The memory controller 211 may store codes representing the operating frequency, timing, drivers, detailed operation parameters, etc. of the HBM 200 to the MRS 204 according to the specifications of the HBM 200, such that the memory controller 211 may normally interoperate with the HBM 200. For example, the MRS 204 may store a burst length BL, a read latency RL, and operation parameter codes associated with the first HBM PHY 202a and the second HBM PHY 202b, etc. The burst length BL may be provided to set the maximum number of column locations that may be accessed for a read command and/or a write command. The read latency RL may be provided to define a clock cycle delay between a read command and a first bit of valid output data. The operation parameter codes associated with the first HBM PHY 202a and the second HBM PHY 202b may be provided to define a PHY operation mode and a multi-PHY connection sequence, as shown in FIG. 3.

Referring to FIG. 2B, unlike the system 20 of FIG. 2A, in the system 20a, the HBM 200 includes three HBM PHYs, that is, the first HBM PHY 202a, the second HBM PHY 202b, and a third HBM PHY 202c, and the third HBM PHY 202c is activated or deactivated by a third selection signal PS3 provided from the controller PHY 212 to the third HBM PHY 202c. When the third selection signal PS3 is at a logic high level, the third HBM PHY 202c may be activated, and, when the third selection signal PS3 is at a logic low level, the third HBM PHY 202c may be deactivated. As explained above, the different logic values may respectively correspond to different signal voltage levels. According to some embodiments, the HBM 200 may be expanded to include n (n is a natural number equal to or greater than 3) HBM PHYs, which may be designed to divide some of a plurality of jobs or tasks executed on the CPU 210 into small jobs and perform the small jobs in the n HBM PHYs in parallel. For convenience of explanation, it will be described that the HBM 200 has the first HBM PHY 202a and the second HBM PHY 202b, and the same will be applied to embodiments below.

Referring to FIG. 3, the MRS 204 may include first to fourth mode registers 302, 304, 306, and 308 that store operation parameter codes associated with the first HBM PHY 202a and the second HBM PHY 202b. The first to fourth mode registers 302, 304, 306, and 308 may be identified by their respective mode register addresses. A first mode register 302 may be identified by a first mode register address MR_A, a second mode register 304 may be identified by a second mode register address MR_B, a third mode register 306 may be identified by a third mode register address MR_C, and a fourth mode register 308 may be identified by a fourth mode register address MR_D.

The first mode register 302 may store PHY mode parameters indicating whether a single PHY mode or a multi-PHY mode is supported for the first HBM PHY 202a and the second HBM PHY 202b. A PHY mode parameter may be expressed by an 1-bit parameter code. For example, a bit value “0” stored in a register OP[0] of the first mode register 302 may indicate the single PHY mode in which one HBM PHY of the first HBM PHY 202a and the second HBM PHY 202b is activated, and a bit value “1” stored in the register OP[0] may indicate the multi-PHY mode in which both the first HBM PHY 202a and the second HBM PHY 202b are activated. Conversely, the bit value “0” stored in the register OP[0] may indicate the multi-PHY mode, and the bit value “1” stored in the register OP[0] may indicate the single PHY mode. According to some embodiments, the PHY mode parameter code for the first HBM PHY 202a and the second HBM PHY 202b may include more than 1 bit.

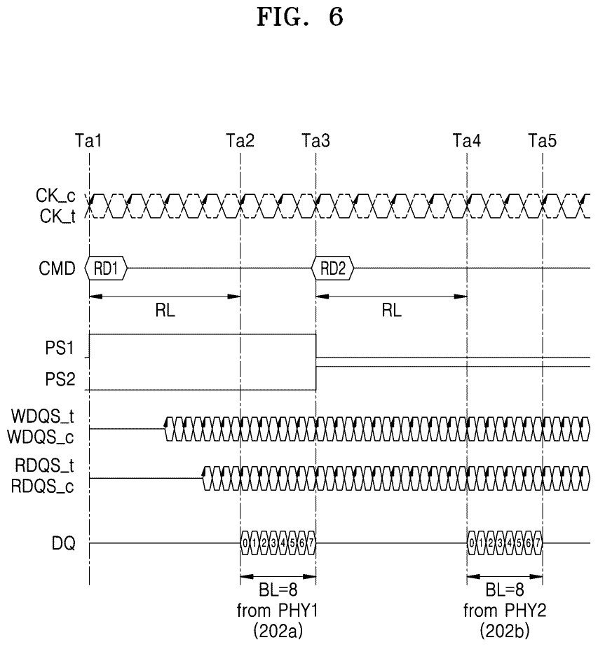

In the single PHY mode, the HBM 200 may perform data communication between each of the first HBM PHY 202a and the second HBM PHY 202b and the memory controller 211 according to respective logic levels of the first selection signal PS1 and the second selection signal PS2 selectively provided by the memory controller 211. For example, according to the logic high level of the first selection signal PS1, the first HBM PHY 202a may be connected to the bus 230 to perform data communication between the memory controller 211 and the first HBM PHY 202a, and, according to the logic high level of the second selection signal PS2, the second HBM PHY 202b may be connected to the bus 230 to perform data communication between the memory controller 211 and the second HBM PHY 202b (e.g., FIG. 6).

In the multi PHY mode, the HBM 200 may perform data communications between the first HBM PHY 202a and the second HBM PHY 202b and the memory controller 211 according to the logic high level of the first selection signal PS1 and the second selection signal PS2 substantially simultaneously provided by the memory controller 211. At this time, the first HBM PHY 202a and the second HBM PHY 202b need to perform data communications with the memory controller 211 through the bus 230 in a specific sequence. In other words, the multi PHY mode set in the first mode register 302 may be supported along with an order that the first HBM PHY 202a and the second HBM PHY 202b are connected to the bus 230.

The second mode register 304 may store a multi PHY connection order parameter indicating the order that the first HBM PHY 202a and the second HBM PHY 202b are connected to the bus 230. The multi PHY connection order parameter may be expressed by a 2-bit parameter code. A bit value “00” stored in the register OP[1:0] of the second mode register 304 is a default value and may indicate that a multi PHY connection order is disabled. For example, when the single PHY mode is set in the first mode register 302, it is not necessary to set the multi PHY connection order, and thus the multi PHY connection order is disabled.

A bit value “01” stored in the register OP[1:0] of the second mode register 304 may indicate an order that the first HBM PHY 202a is connected to the bus 230 first and the second HBM PHY 202b is connected to the bus 230 later, and a bit value “10” stored in the register OP[1:0] may indicate an order that the second HBM PHY 202b is connected to the bus 230 first and the first HBM PHY 202a is connected to the bus 230 later. Conversely, the bit value “01” stored in the register OP[1:0] of the second mode register 304 may indicate an order that the second HBM PHY 202b is connected to the bus 230 first and the first HBM PHY 202a is connected to the bus 230 later, and the bit value “10” stored in the register OP[1:0] may indicate an order that the first HBM PHY 202a is connected to the bus 230 first and the second HBM PHY 202b is connected to the bus 230 later. According to some embodiments, the multi PHY connection order parameter codes for the first HBM PHY 202a and the second HBM PHY 202b may include more than 2 bits.

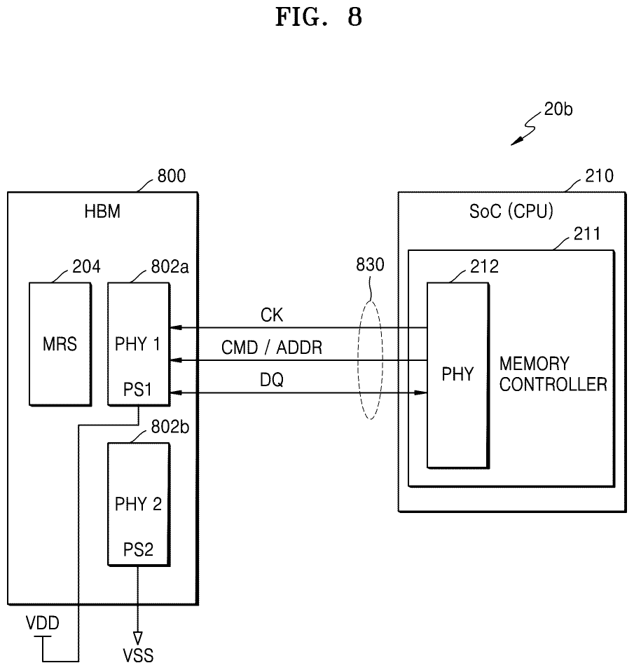

Meanwhile, in the multi PHY mode, an HBM (e.g., 800 of FIG. 8) in which a multi PHY connection order of the first HBM PHY 202a and the second HBM PHY 202b may be specified without providing the first selection signal PS1 and the second selection signal PS2 to the HBM 200 may be provided. As shown in FIG. 8, the first selection signal PS1 of a first HBM PHY 802a is fixed to the voltage level of the power voltage VDD, and the second selection signal PS2 of a second HBM PHY 802b may be fixed to the voltage level of the ground voltage VSS. The HBM 800 may provide a multi PHY connection order, such that the first HBM PHY 802a is connected to the data bus 230 first based on the first selection signal PS1 of the first HBM PHY 802a at the voltage level of the power voltage VDD and the second HBM PHY 802b is connected to the data bus 230 after the first HBM PHY 802a. The multi PHY connection order provided by the HBM 800 may be planned in advance by agreement with the memory controller 211. Therefore, the register OP[1:0] of the second mode register 304 may be set to a default value, such that the multi PHY connection order is not provided by the second mode register 304.

The third mode register 306 may store an HBM version parameter indicating whether the HBM 200 is an HBM3 product or an HBM4 product. The HBM version parameter may be expressed by an 1-bit parameter code. For example, a bit value “0” stored in the register OP[0] of the third mode register 306 may indicate an HBM3 product, and a bit value “1” stored in the register OP[0] may indicate an HBM4 product. Conversely, the bit value “0” stored in the register OP[0] of the third mode register 306 may indicate an HBM4 product, and the bit value “1” stored in the register OP[0] of the third mode register 306 may indicate an HBM3 product. According to some embodiments, the HBM version parameter code for the HBM 200 may include more than 1 bit.

The fourth mode register 308 may store an HBM model name parameter indicating the model name of the HBM 200. An HBM IC specific number parameter code may be expressed as a vendor-specific 8-bit parameter code.

FIG. 4 is a diagram that illustrates a memory device according to embodiments.

Referring to FIGS. 2A, 3, and 4, a memory device 200 may be an HBM including the plurality of channels CH1 to CH8 having access interfaces independent from one another. The HBM 200 may include a plurality of dies including a buffer die 222 and a DRAM die stack 240 stacked on the buffer die 222. The DRAM die stack 240 may include four DRAM dies 240a to 240d, and the DRAM dies 240a to 240d may support eight channels CH1 to CH8. For example, a first DRAM die 240a may include a first channel CH1 and a third channel CH3, a second DRAM die 240b may include a second channel CH2 and a fourth channel CH4, a third DRAM die 240c may include a fifth channel CH5 and a seventh channel CH7, and a fourth DRAM die 240d may include a sixth channel CH6 and an eighth channel CH8. Although the present embodiment shows that the HBM 200 includes four DRAM dies 240a to 240d, embodiments of the inventive concept are not limited thereto, and 4 to 16 DRAM dies may be stacked to support 16 channels.

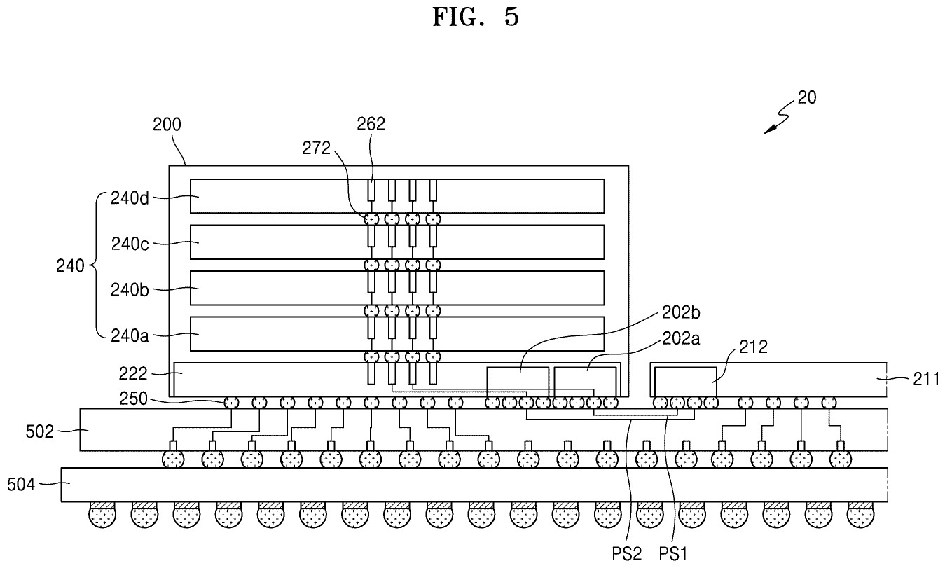

The buffer die 222 may communicate with the memory controller 211 through conductive means formed on the outer surface of the HBM 200, e.g., bumps or solder balls (e.g., 250 of FIG. 5). The buffer die 222 may receive the command/address CMD/ADDR and the data DQ from the memory controller 211 and provide the command/address CMD/ADDR and the data DQ to an access channel of the DRAM die stack 240. Also, the buffer die 222 may provide the data DQ output from the access channel of the DRAM die stack 240 to the memory controller 211.

The HBM 200 may include a plurality of through silicon vias (TSVs) 262 penetrating or extending through the DRAM dies 240a to 240d of the DRAM die stack 240. When each of the channels CH1 to CH8 has a bandwidth of 128 bits, the TSVs 262 may include components for inputting/outputting data of 1024 bits. Each of the channels CH1 to CH8 may be separated into two pseudo channels. For example, in the fourth DRAM die 240d, the sixth channel CH6 may be divided into pseudo channels CH6a and CH6b and the eighth channel CH6 may be divided into pseudo channels CH8a and CH8b. Each of pseudo channels CH6a, CH6b, CH8a, and CH8b may include 64-bit data DQ. The TSVs 262 may be arranged between the pseudo channels CH6a and CH6b of the sixth channel CH6 and between pseudo channels CH8a and CH8b of the eighth channel CH8.

The buffer die 222 may include the MRS 204, the first HBM PHY 202a, and the second HBM PHY 202b. The MRS 204 may store parameter codes indicating a PHY operation mode and a multi PHY connection order for the first HBM PHY 202a and the second HBM PHY 202b. The first HBM PHY 202a may be activated by the first selection signal PS1, may transmit the clock signal CK, the command/address CMD/ADDR, and the data DQ received from the memory controller 211 through the bus 230 to each of the channels CH1 to CH8, and may transmit the data DQ output from each of the channels CH1 to CH8 to the memory controller 211 through the bus 230. The second HBM PHY 202b may be activated by the second selection signal PS2, may transmit the clock signal CK, the command/address CMD/ADDR, and the data DQ received from the memory controller 211 through the bus 230 to each of the channels CH1 to CH8, and may transmit the data DQ output from each of the channels CH1 to CH8 to the memory controller 211 through the bus 230. The first HBM PHY 202a and the second HBM PHY 202b may be configured to be identical to each other, except that the first HBM PHY 202a and the second HBM PHY 202b are activated by the first selection signal PS1 and the second selection signal PS2, respectively.

FIG. 5 is a diagram that illustrates a portion of a semiconductor package implementing a system according to embodiments.

Referring to FIGS. 2A, 4, and 5, the system 20 may include the HBM 200, the memory controller 211, an interposer 502, and a printed circuit board (PCB) 504. The HBM 200 may include the buffer die 222 and the DRAM die stack 240, and the DRAM die stack 240 may include first to fourth DRAM dies 240a to 240d. The buffer die 222 may include the first HBM PHY 202a and the second HBM PHY 202b.

The DRAM die stack 240 may include the TSVs 262. A TSV 262 is an electrode formed by forming a hole in a wafer through laser drilling or chemical etching such as deep reactive ion etching (DRIE) and filling the hole through plating. The first to fourth DRAM dies 240a to 240d of the DRAM die stack 240 may be stacked through the TSVs 262 and electrically connected to one another through bumps 272. The bumps 272 are conductive protrusions that may electrically interconnect the first to fourth DRAM dies 240a to 240d and the buffer die 222.

The memory controller 211 may control the HBM 200 by transmitting various commands needed for operation of the HBM 200 to the HBM 200. The memory controller 211 may perform data communication to store specific data in the HBM 200 or to read data stored in the HBM 200. The memory controller 211 may perform data communication with the HBM 200 through the first HBM PHY 202a and the second HBM PHY 202b. For example, the memory controller 211 may perform data communication by using any one of the first HBM PHY 202a and the second HBM PHY 202b or both of them. Parameter codes indicating a PHY operation mode and a multi PHY connection order for the first HBM PHY 202a and the second HBM PHY 202b used for data communication with the memory controller 211 may be set to the MRS 204 (FIG. 3).

The interposer 502 may buffer the difference between circuit line widths of the HBM 200 and the PCB 504. The interposer 502 is an electrical interface that provides routes between connections to one socket or another to extend electrical wires to a wider pitch or to reroute wires to wires of a different pitch. The interposer 502 may physically connect the HBM 200, the memory controller 211, and the PCB 504. The HBM 200 and the memory controller 211 may transmit and receive data through wires arranged at the interposer 502. A line for the first selection signal PS1 for selecting and activating the first HBM PHY 202a and a line for the second selection signal PS2 for selecting and activating the second HBM PHY 202b may be arranged at the interposer 502.

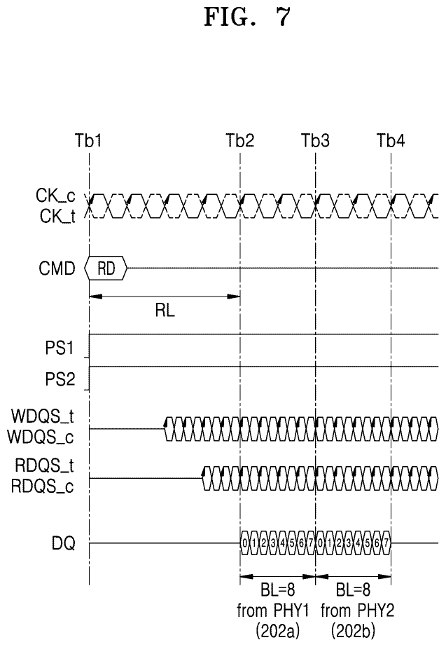

FIGS. 6 and 7 are timing diagrams that illustrate a read operation of a memory device according to embodiments. FIG. 6 illustrates a read operation for the first HBM PHY 202a and the second HBM PHY 202b when the HBM 200 is in the single PHY mode, and FIG. 7 illustrates a read operation for the first HBM PHY 202a and the second HBM PHY 202b when the HBM 200 is in the multi PHY mode. In the timing diagrams described below, the horizontal axis and the vertical axis represent time and voltage levels, respectively, and are not necessarily drawn to scale.

Referring to FIGS. 2A, 3, and 6, for a read operation on the HBM 200, a first read command RD1 synchronized to the clock signal CK may be applied at a time point Ta1. It is assumed that the single PHY mode is set to the MRS 204 of the HBM 200 for the first HBM PHY 202a and the second HBM PHY 202b before the time point Ta1. At the time point Ta1, together with the first read command RD1, a column address designating memories of the channels CH1 to CH8 on which the read operation is to be performed and the first selection signal PS1 of the logic high level may be received. The first HBM PHY 202a may be activated in response to the first selection signal PS1 being at a logic high level. After the read latency RL is clapsed from the time point Ta1, read data DQ having a certain burst length BL (e.g., BL=8) output from the first HBM PHY 202a may be synchronized to a clock signal RDQS and output to the data bus 230 at a time point Ta2. The read data DQ of the first HBM PHY 202a according to the first read command RD1 and the first selection signal PS1 may be synchronized to the clock signals RDQS and output from time point Ta2 to a time point Ta3. In response to demands for a high data transmission rate, according to the present embodiment, the clock signal WDQS and the clock signal RDQS may each be configured to have a frequency higher than that of the frequency of the clock signal CK, e.g., twice the clock signal CK frequency. According to another embodiment, the clock signal WDQS and the clock signal RDQS may each be set to have a frequency four times the frequency of the clock signal CK.

At the time point Ta3, a second read command RD2 synchronized to the clock signal CK may be applied. Together with the second read command RD2, a column address designating memories of the channels CH1 to CH8 on which the read operation is to be performed and the second selection signal PS2 at the logic high level may be received. At this time, the first selection signal PS1 may be received at a logic low level. The first HBM PHY 202a may be deactivated in response to the first selection signal PS1 being at the logic low level, and the second HBM PHY 202b may be activated in response to the second selection signal PS2 being at the logic high level. After the read latency RL is elapsed from the time point Ta3, read data DQ corresponding to the burst length BL=8 output from the second HBM PHY 202b may be synchronized to the clock signal RDQS and output to the data bus 230 at a time point Ta4. The read data DQ of the second HBM PHY 202b according to the second read command RD2 and the second selection signal PS2 may be synchronized to the clock signal RDQS and output from the time point Ta4 to a time point Ta5.

Referring to FIGS. 2A, 3, and 7, for a read operation on the HBM 200, a read command RD synchronized to the clock signal CK may be applied at a time point Tb1. It is assumed that a multi PHY connection order is set to the MRS 204 of the HBM 200 for the first HBM PHY 202a and the second HBM PHY 202b and a multi PHY connection order is configured to connect the second HBM PHY 202b after the first HBM PHY 202a is connected, before the time point Tb1. At the time point Tb1, together with the read command RD, a column address designating memories of the channels CH1 to CH8 on which the read operation is to be performed and the first selection signal PS1 and the second selection signal PS2 for activating the first HBM PHY 202a and the second HBM PHY 202b may be received at a logic high level.

After read latency RL is elapsed from the time point Tb1, at a time point Tb2, the first HBM PHY 202a may prepare to output the read data DQ having the burst length BL=8, and the second HBM PHY 202b may also prepare to output the read data DQ having the burst length BL=8. According to the multi PHY connection order stored in the MRS 204, the read data DQ of the first HBM PHY 202a may be output first to the data bus 230, and then the read data DQ of the second HBM PHY 202b may be output to the data bus 230. In synchronization with the clock signal RDQS, the read data DQ of the first HBM PHY 202a may be output from the time point Tb2 to a time point Tb3, and the read data DQ of the second HBM PHY 202b may be output from the time point Tb3 to a time point Tb4.

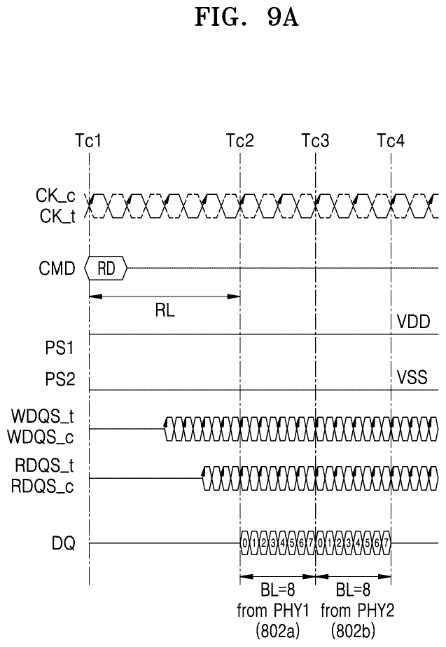

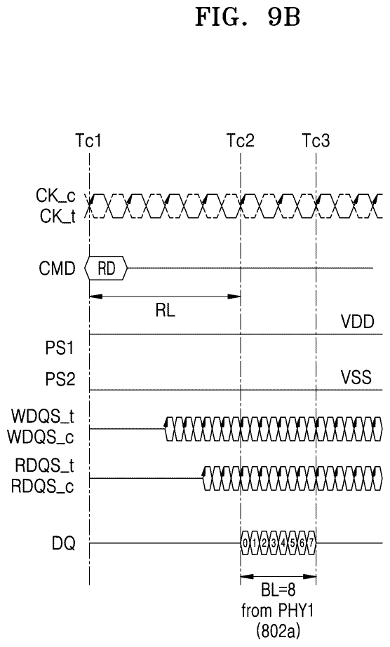

FIGS. 8, 9a and 9B are diagrams that illustrate a memory device according to embodiments. FIG. 8 shows the HBM 800 in which the first selection signal PS1 and the second selection signal PS2 of the first HBM PHY 802a and the second HBM PHY 802b are fixed by way of hardware to a specific voltage level, and FIG. 9A and FIG. 9B are timing diagrams for describing the operation of the HBM 800 of FIG. 8.

Referring to FIG. 8, a system 20b may include the CPU 210 including the HBM 800 having the first HBM PHY 802a and the second HBM PHY 802b and the memory controller 211 having the controller PHY 212. As compared to the system 20 of FIG. 2A, in the system 20b,a bus 830 connected between the controller PHY 212 and the HBM 800 does not include a line for the first selection signal PS1 and a line for the second selection signal PS2. Also, the first selection signal PS1 and the second selection signal PS2 for the first HBM PHY 802a and the second HBM PHY 802b are fixed by way of hardware to a specific voltage level. Hereinafter, descriptions similar or identical to those of the system 20 will be omitted.

The system 20b may be configured to perform a multi PHY mode operation on the first HBM PHY 802a and the second HBM PHY 802b of the HBM 800, as shown in FIG. 9A. The memory controller 211 and the HBM 800 may agree on a multi PHY connection order for the first HBM PHY 802a and the second HBM PHY 802b in a multi PHY mode in advance. For example, it may be agreed, such that an HBM PHY corresponding to a selection signal at the voltage level of the power voltage VDD from between the first selection signal PS1 and the second selection signal PS2 for the first HBM PHY 202a and the second HBM PHY 202b is connected to the bus 830 first and the other HBM PHY is connected to the bus 830 after the initial HBM PHY is connected. Conversely, it may be agreed, such that an HBM PHY corresponding to a selection signal at the voltage level of the ground voltage VSS is connected to the bus 830 first and the HBM PHY corresponding to the selection signal at the voltage level of the power voltage VDD is connected to the bus 830 after the initial HBM PHY is connected.

The system 20b may be configured to perform a single PHY mode operation on the first HBM PHY 802a and the second HBM PHY 802b of the HBM 800, as shown in FIG. 9B. The memory controller 211 and the HBM 800 may agree on an HBM PHY to be activated from between the first HBM PHY 802a and the second HBM PHY 802b in the single PHY mode in advance. For example, it may be agreed, such that an HBM PHY corresponding to the selection signal at the voltage level of the power voltage VDD from between the first selection signal PS1 and the second selection signal PS2 for the first HBM PHY 202a and the second HBM PHY 202b is activated. Conversely, it may be agreed, such that the HBM PHY corresponding to the selection signal at the voltage level of the ground voltage VSS is activated.

For example, the first selection signal PS1 of the first HBM PHY 802a may be connected to a line of the power voltage VDD, and the second selection signal PS2 of the second HBM PHY 802b may be connected to a line of the ground voltage VSS. Such line connections of the first selection signal PS1 and the second selection signal PS2 for the first HBM PHY 802a and the second HBM PHY 802b may be implemented by using the interposer 502 (FIG. 5) during a package manufacturing operation for the system 20b. According to some embodiments, a line of the power voltage VDD or a line of the ground voltage VSS may be connected to the first selection signal PS1 and the second selection signal PS2 for the first HBM PHY 802a and the second HBM PHY 802b by using a redistribution layer disposed in the buffer die 222 (FIG. 5) of the HBM 800.

Referring to FIGS. 8 and 9A, for a read operation on the HBM 800, the read command RD synchronized to the clock signal CK may be applied at a time point Tel. It is assumed that, before the time point Tc1, the first selection signal PS1 for the first HBM PHY 802a is connected to a line of the power voltage VDD, the second selection signal PS2 for the second HBM PHY 802b is connected to a line of the ground voltage VSS, the multi PHY mode is set to the MRS 204 of the HBM 800 for the first HBM PHY 802a and the second HBM PHY 802b, and the multi PHY connection order is set to be disabled. At the time point Tel, together with the read command RD, a column address designating memories of the channels CH1 to CH8 on which the read operation is to be performed may be received. After read latency RL is elapsed from the time point Tc1, at a time point Tc2, the first HBM PHY 802a may prepare to output the read data DQ having the burst length BL=8, and the second HBM PHY 802b may also prepare to output the read data DQ having the burst length BL=8. Based on voltage level of the first selection signal PS1 for the first HBM PHY 802a equal to that of the power voltage VDD, the read data DQ of the first HBM PHY 802a may be output first to the data bus 830, and then the read data DQ of the second HBM PHY 802b may be output to the data bus 830. In synchronization with the clock signal RDQS, the read data DQ of the first HBM PHY 802a may be output from the time point Tc2 to a time point Tc3, and the read data DQ of the second HBM PHY 802b may be output from the time point Tc3 to a time point Tc4.

Referring to FIGS. 8 and 9B, for a read operation on the HBM 800, the read command RD synchronized to the clock signal CK and column address designating memories of the channels CH1 to CH8 on which the read operation is to be performed may be received at the time point Tc1. It is assumed that, before the time point Tel, the first selection signal PS1 for the first HBM PHY 802a is connected to a line of the power voltage VDD, the second selection signal PS2 for the second HBM PHY 802b is connected to a line of the ground voltage VSS, and the single PHY mode is set to the MRS 204 of the HBM 800 for the first HBM PHY 802a and the second HBM PHY 802b. The first HBM PHY 802a may be activated and prepare to output the read data DQ having the burst length BL=8 based on the first selection signal PS1 at the voltage level of the power voltage VDD, and the second HBM PHY 802b may be deactivated based on the second selection signal PS2 at the voltage level of the ground voltage VSS. After the read latency RL is elapsed from the time point Tel, the read data DQ of the first HBM PHY 802a may be output in synchronization with the clock signal RDQS at the time point Tc2.

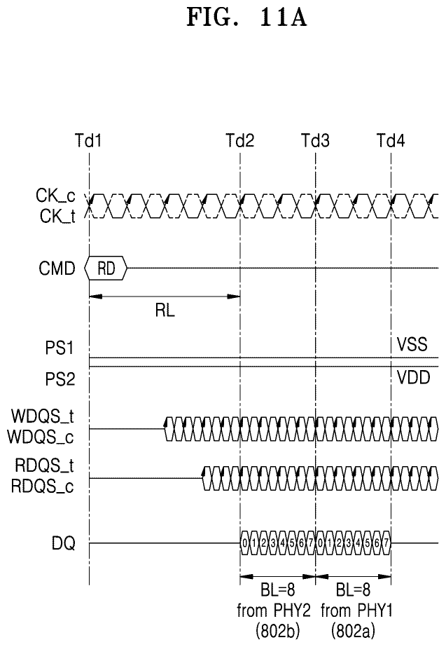

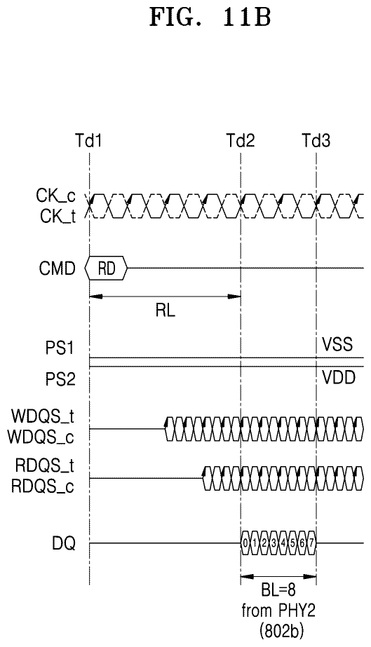

FIGS. 10, 11a and 11B are diagrams that illustrate a memory device according to embodiments. FIG. 10 is a diagram showing the HBM 800 in which the first selection signal PS1 and the second selection signal PS2 for the first HBM PHY 802a and the second HBM PHY 802b are fixed by way of hardware to voltage levels opposite to those shown in FIG. 8, and FIGS. 11A and 11B are timing diagrams that illustrate the operation of the HBM 800 of FIG. 10. Hereinafter, descriptions similar or identical to those of the system 20b of FIG. 8 will be omitted.

Referring to FIG. 10, in a system 20c, the bus 830 connected between the controller PHY 212 and the HBM 800 may be connected to the second HBM PHY 802b of the HBM 800. The first selection signal PS1 of the first HBM PHY 802a may be connected to a line of the ground voltage VSS, and the second selection signal PS2 of the second HBM PHY 802b may be connected to a line of the power voltage VDD. Such line connections of the first selection signal PS1 and the second selection signal PS2 for the first HBM PHY 802a and the second HBM PHY 802b may be implemented at the interposer 502 or the redistribution layer of the buffer die 222 during a package manufacturing operation for the system 20c.

Referring to FIGS. 10 and 11A, for a read operation on the HBM 800, the read command RD synchronized to the clock signal CK may be applied at a time point Td1. It is assumed that, before the time point Td1, the first selection signal PS1 for the first HBM PHY 802a is connected to a line of the ground voltage VSS, the second selection signal PS2 for the second HBM PHY 802b is connected to a line of the power voltage VDD, the multi PHY mode is set to the MRS 204 of the HBM 800 for the first HBM PHY 802a and the second HBM PHY 802b, and the multi PHY connection order is set to be disabled. At the time point Td1, together with the read command RD, a column address designating memories of the channels CH1 to CH8 on which the read operation is to be performed may be received. After read latency RL is elapsed from the time point Td1, at a time point Td2, the first HBM PHY 802a may prepare to output the read data DQ having the burst length BL=8, and the second HBM PHY 802b may also prepare to output the read data DQ having the burst length BL=8. Based on voltage level of the second selection signal PS2 for the second HBM PHY 802b equal to that of the power voltage VDD, the read data DQ of the second HBM PHY 802b may be output first to the data bus 830, and then the read data DQ of the first HBM PHY 802a may be output to the data bus 830. In synchronization with the clock signal RDQS, the read data DQ of the second HBM PHY 802b may be output from the time point Td2 to a time point Td3, and the read data DQ of the first HBM PHY 802a may be output from the time point Td3 to a time point Td4.

Referring to FIGS. 10 and 11B, for a read operation on the HBM 800, the read command RD synchronized to the clock signal CK and column address designating memories of the channels CH1 to CH8 on which the read operation is to be performed may be received at the time point Td1. It is assumed that, before the time point Td1, the first selection signal PS1 for the first HBM PHY 802a is connected to a line of the ground voltage VSS, the second selection signal PS2 for the second HBM PHY 802b is connected to a line of the power voltage VDD, and the single PHY mode is set to the MRS 204 of the HBM 800 for the first HBM PHY 802a and the second HBM PHY 802b. The second HBM PHY 802b may be activated and prepare to output the read data DQ having the burst length BL=8 based on the second selection signal PS2 at the voltage level of the power voltage VDD, and the first HBM PHY 802a may be deactivated based on the first selection signal PS1 at the voltage level of the ground voltage VSS. After the read latency RL is elapsed from the time point Td1, the read data DQ of the second HBM PHY 802b may be output in synchronization with the clock signal RDQS at the time point Td2.

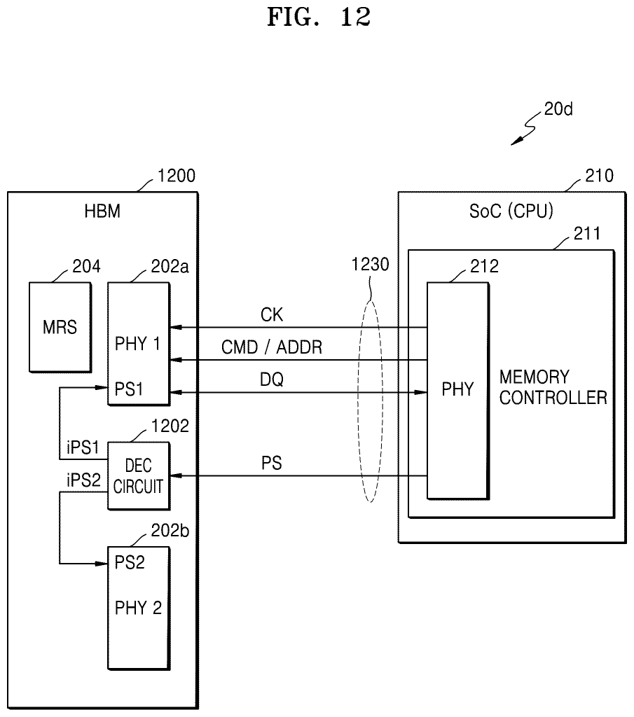

FIG. 12 is a diagram that illustrates a memory device according to embodiments. FIG. 12 shows an HBM 1200 in which the first HBM PHY 202a and the second HBM PHY 202b are activated by first internal selection signal iPS1 and the second internal selection signal iPS2 generated inside the HBM 1200. Hereinafter, descriptions similar or identical to those of the system 20b of FIG. 2A will be omitted.

Referring to FIG. 12, as compared to the system 20 of FIG. 2A, a system 20d may include a line of a PHY selection signal PS in a bus 1230 connected between the controller PHY 212 and the HBM 1200, and the HBM 1200 may include a decoder circuit 1202. The decoder circuit 1202 may be disposed on the buffer die 222 (FIGS. 4 and 5) of the HBM 1200. According to the present embodiment, it is shown that the PHY selection signal PS is provided through one signal line. However, according to some embodiments, the PHY selection signal PS having various numbers of bits in correspondence to n HBM PHYs may be provided.

The decoder circuit 1202 may decode the PHY selection signal PS provided from the memory controller 211 and generate the first internal selection signal iPS1 and the second internal selection signal iPS2. The first internal selection signal iPS1 may be provided to the first HBM PHY 202a, and the first HBM PHY 202a may be activated in response to the first internal selection signal iPS1 at a logic high level. The second internal selection signal iPS2 may be provided to the second HBM PHY 202b, and the second HBM PHY 202b may be activated in response to the second internal selection signal iPS2 at a logic high level. For example, when the PHY selection signal PS is provided at a logic low level, the decoder circuit 1202 may output the first internal selection signal iPS1 at a logic high level and the second internal selection signal iPS2 at the logic low level. When the PHY selection signal PS at the logic high level is provided, the decoder circuit 1202 may output the first internal selection signal iPS1 at the logic low level and the second internal selection signal iPS2 at the logic high level. According to some embodiments, the decoder circuit 1202 may be implemented as a demultiplexer circuit.

In the system 20d, the memory controller 211 may set the single PHY mode to the MRS 204 of the HBM 1200. The memory controller 211 may activate any one HBM PHY from between the first HBM PHY 202a and the second HBM PHY 202b by using the logic level of the PHY selection signal PS and perform data communication with an activated HBM PHY through the bus 1230.

In the system 20d, the memory controller 211 may set the multi PHY mode to the MRS 204 of the HBM 1200 and set a multi PHY connection order to a default value (disabled). The memory controller 211 may perform data communications between each of the first HBM PHY 202a and the second HBM PHY 202b and the memory controller 211 by using the logic level of the PHY selection signal PS. For example, the memory controller 211 may provide the PHY selection signal PS at the logic low level to perform data communication with the first HBM PHY 802a first and perform data communication with the second HBM PHY 802b after the first PHY 802a. Alternatively, the memory controller 211 may provide the PHY selection signal PS of the logic high level to perform data communication with the second HBM PHY 802b first and perform data communication with the first HBM PHY 802a after the second HBM PHY 802b.

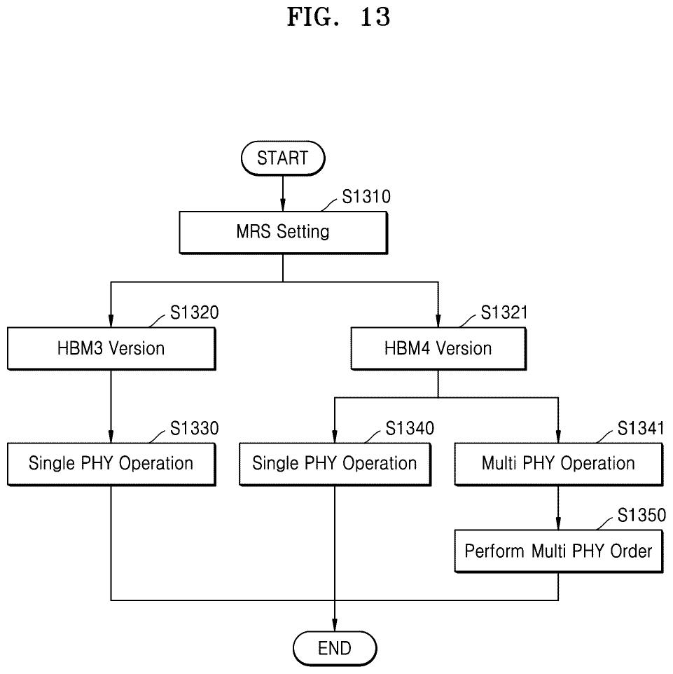

FIG. 13 is a flowchart that illustrates the operation of a memory device according to embodiments.

Referring to FIG. 13 in conjunction with FIGS. 2A to 12, after power is supplied to the system 20 and the system 20 is powered up, the memory controller 211 may set up the MRS 204 that configures a plurality of operational options, various functions, features, and modes of the HBM 200 (operation S1310). For the HBM 200, the MRS 204 may store the HBM version parameter indicating whether the HBM 200 is an HBM3 product or an HBM4 product, the HBM model name parameter, the PHY mode parameter indicating whether the HBM 200 supports the single PHY mode or the multi-PHY mode, and the multi PHY connection order parameter.

The HBM 200 may perform a control operation to operate according to the HBM3 version in operation S1320. The HBM 200 may perform a control operation to operate according to the HBM4 version in operation S1321.

Based on the HBM3 version determined in operation S1320, HBM 200 may operate in the single PHY mode (operation S1330). In the single PHY mode of the HBM3, the HBM 200 may control the first HBM PHY 202a and the second HBM PHY 202b to perform data communication with the memory controller 211 based on the logic levels of the first selection signal PS1 and the second selection signal PS2 selectively provided by the memory controller 211, respectively.

Based on the HBM4 version determined in operation S1321, the HBM 200 may operate in the single PHY mode (operation S1340) or the multi PHY mode (operation S1341). In the single PHY mode of the HBM4, the HBM 200 may control the first HBM PHY 202a and the second HBM PHY 202b to perform data communication with the memory controller 211 based on the logic levels of the first selection signal PS1 and the second selection signal PS2 selectively provided by the memory controller 211, respectively. In the multi PHY mode of the HBM4, the HBM 200 may connect the first HBM PHY 202a and the second HBM PHY 202b to the bus 230 in the order set in the multi PHY connection order parameter and control each of the first HBM PHY 202a and the second HBM PHY 202b to perform data communication with the memory controller 211 according to the multi PHY connection order.

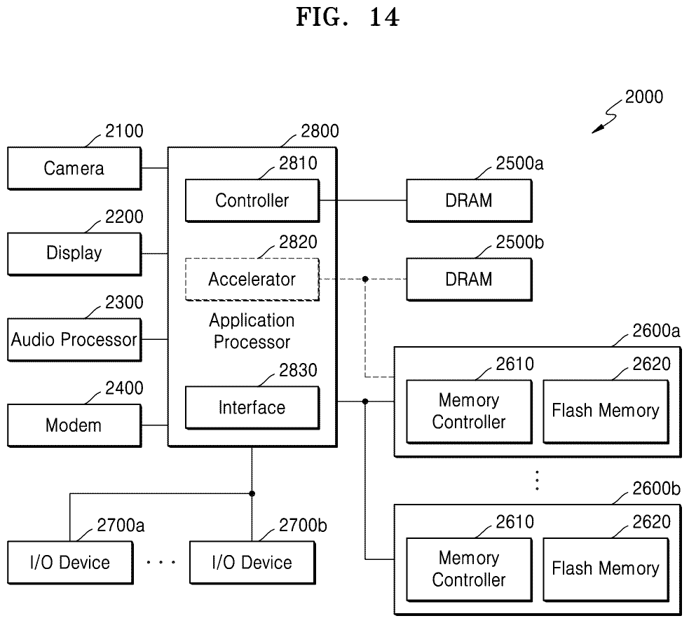

FIG. 14 is a block diagram of a system 2000 that illustrates an electronic device including a memory device according to embodiments.

Referring to FIG. 14, the system 2000 may include a camera 2100, a display 2200, an audio processor 2300, a modem 2400, DRAMs 2500a and 2500b, flash memories 2600a and 2600b, I/O devices 2700a and 2700b, and an application processor (AP) 2800. The system 2000 may be implemented as a laptop computer, a mobile phone, a smartphone, a tablet PC, a wearable device, a healthcare device, or an IoT device. Also, the system 2000 may be implemented as a server or a PC.

The camera 2100 may capture a still image or a video according to a user's control and may store captured image/video data or transmit the captured image/video data to the display 2200. The audio processor 2300 may process audio data included in the flash memories 2600a and 2600b or network content. The modem 2400 may transmit a modulated signal for wired/wireless data transmission/reception to a receiver and the modulated signal may be demodulated by the receiver to restore an original signal. The I/O devices 2700a and 2700b may include devices providing a digital input function and/or digital output function, e.g., a Universal Serial Bus (USB), a storage, a digital camera, a Secure Digital (SD) card, a Digital Versatile Disc (DVD), a network adapter, a touch screen, etc.

The AP 2800 may control the overall operation of the system 2000. The AP 2800 may include a control block 2810, an accelerator block or accelerator chip 2820, and an interface block 2830. The AP 2800 may control the display 2200, such that a part of content stored in the flash memories 2600a and 2600b is displayed on the display 2200. When a user input is received through the I/O devices 2700a and 2700b, the AP 2800 may perform a control operation corresponding to the user input. The AP 2800 may include an accelerator block, which is a circuit dedicated for calculation of Artificial Intelligence (AI) data, or may include an accelerator chip 2820 separately from the AP 2800. The DRAM 2500b may be additionally provided in the accelerator block or the accelerator chip 2820. The accelerator block is a functional block that specializes in performing a particular function of the AP 2800 and may include a GPU, which is a functional block that specializes in processing graphic data, a neural processing unit (NPU), which is a block that specializes in AI calculation and inference, and a data processing unit (DPU), which is a block that specializes in data transmission.

The system 2000 may include a plurality of DRAMs 2500a and 2500b. The AP 2800 may set up a DRAM interface protocol and communicate with the DRAMs 2500a and 2500b to control the DRAMs 2500a and 2500b through commands complying with the Joint Electron Device Engineering Council (JEDEC) standard and mode register (MRS) setting or to use company-specific functions such as low voltage/high-speed/reliability and a cyclic redundancy check (CRC)/error correction code (ECC) function. For example, the AP 2800 may communicate with the DRAM 2500a through an interface complying with the JEDEC standards such as LPDDR4 and LPDDR5, and the accelerator block or the accelerator chip 2820 may set and use a new DRAM interface protocol to control the DRAM 2500b for an accelerator, which has a greater bandwidth than the DRAM 2500a.

Although FIG. 14 shows only the DRAMs 2500a and 2500b, embodiments of the inventive concept is not limited thereto. As long as a bandwidth, a response speed, and voltage conditions of the AP 2800 or the accelerator chip 2820 are satisfied, any memory like a PRAM, an SRAM, an MRAM, an RRAM, an FRAM, or a Hybrid RAM may be used. The DRAMs 2500a and 2500b have relatively smaller latency and bandwidth than the I/O devices 2700a and 2700b or the flash memories 2600a and 2600b. The DRAMs 2500a and 2500b are initialized when the system 2000 is powered on and the OS and application data are loaded thereto, and thus the DRAMs 2500a and 2500b may be used as temporary storage locations for the OS and the application data or may be used as execution spaces for various software code.

In the DRAMs 2500a and 2500b, four arithmetic operations (i.e., addition, subtraction, multiplication, and division), vector calculations, address calculations, or Fast Fourier Transform (FFT) calculations may be performed. Also, in the DRAMs 2500a and 2500b, a function for an operation used for an inference may be performed, e.g., an AI operation. Here, the inference may be performed in a deep learning algorithm using an artificial neural network. The deep learning algorithm may include operations for training a model through various data and operations for operating the model in inference or prediction mode for recognizing data with the trained model. According to an embodiment, an image captured by a user through the camera 2100 is signal-processed and stored in the DRAM 2500b, and the accelerator block or accelerator chip 2820 may perform AI data calculation for recognizing data using data stored in the DRAM 2500b and a trained model used for inference.

The system 2000 may include a plurality of storage entities or flash memories 2600a and 2600b having a larger capacity than the DRAMs 2500a and 2500b. The accelerator block or accelerator chip 2820 may perform a training operation for an AI model and an AI data calculation associated with an inference or prediction when the AI model is in inference mode using the flash memories 2600a and 2600b. According to an embodiment, the flash memories 2600a and 2600b may include a memory controller 2610 and a flash memory device 2620, and a training operation and an inference AI data calculation performed by the AP 2800 and/or the accelerator chip 2820 may be performed more efficiently by using an arithmetic unit included in the memory controller 2610. The flash memories 2600a and 2600b may store images captured through the camera 2100 or data transmitted through a data network. For example, the flash memories 2600a and 2600b may store Augmented Reality/Virtual Reality content, High Definition (HD) content, or Ultra High Definition (UHD) content.

In the system 2000, the DRAMs 2500a and 2500b may include the memory device described above with reference to FIGS. 2A to 13. The memory device may include a buffer die including a first interface circuit and a second interface circuit communicating with a device outside the memory device and a memory die stack mounted on the buffer die and including a plurality of stacked memory dies. The first interface circuit and the second interface circuit may process, in parallel, data transmitted to and received from the plurality of memory dies and, after parallel processing, perform data communication with a memory controller outside or external to the memory device according to a single interface mode or a multi interface mode set to a mode register. A first selection signal and a second selection signal may be provided directly from the memory controller, may be fixed to a voltage level agreed with the memory controller by using a redistribution layer of the buffer die or an interposer of a semiconductor package including the memory device, or may be generated inside the memory device based on an interface selection signal applied by the memory device. The memory device may provide a high-speed and high-performance solution without increasing the chip area of a memory controller, as data processed by a plurality of interface circuits in parallel is transmitted in a single interface mode or a multi interface mode according to operating conditions of one bus and one controller interface circuit.

While the inventive concept has been particularly shown and described with reference to embodiments thereof, it will be understood that various changes in form and details may be made therein without departing from the spirit and scope of the following claims.

What is claimed is:

1. A memory device comprising:
a buffer die comprising a first interface circuit and a second interface circuit configured to communicate with an external device, wherein the first interface circuit is configured to activate responsive to a first selection signal, and the second interface circuit is configured to activate responsive to a second selection signal; and
a memory die stack mounted on the buffer die and including a plurality of memory dies, wherein the plurality of memory dies are electrically connected to the first interface circuit and the second interface circuit,
wherein the first selection signal and the second selection signal are received from a memory controller external to the memory device.

2. The memory device of claim 1, wherein the first interface circuit and the second interface circuit are configured to process, in parallel, data transmitted to and received from the plurality of memory dies.

3. The memory device of claim 2, wherein, after the data is processed in parallel, the memory device is configured to transmit, to the memory controller, first interface circuit data or second interface circuit data based on the first selection signal and the second selection signal.

4. The memory device of claim 1, wherein the buffer die further comprises a mode register configured to store an interface mode parameter code indicating a single interface mode or a multi interface mode to set the single interface mode or the multi interface mode for the first interface circuit and the second interface circuit,
in the single interface mode, communication is performed with the memory controller by using the first interface circuit or the second interface circuit, and,
in the multi interface mode, communication is performed with the memory controller by using both the first interface circuit and the second interface circuit.

5. The memory device of claim 4, wherein the mode register is further configured to store a multi interface connection order parameter code indicating an order in which the first interface circuit and the second interface circuit communicate with the memory controller in the multi interface mode.

6. A memory device comprising:
a buffer die comprising a first interface circuit and a second interface circuit configured to communicate with an external device, wherein the first interface circuit is configured to activate responsive to a first selection signal, and the second interface circuit is configured to activate responsive to a second selection signal; and
a memory die stack mounted on the buffer die and including a plurality of memory dies, wherein the plurality of memory dies are electrically connected to the first interface circuit and the second interface circuit,
wherein, which of the first interface circuit and the second interface circuit is activated to communicate with an external memory controller is based on whether the first selection signal is fixed to a first voltage level or a second voltage level different from the first voltage level and whether the second selection signal is fixed to the first voltage level or the second voltage level.

7. The memory device of claim 6, wherein the first voltage level or the second voltage level of the first selection signal and the second selection signal is provided from a redistribution layer of the buffer die.

8. The memory device of claim 6, wherein the first voltage level or the second voltage level of the first selection signal and the second selection signal is provided from an interposer of a semiconductor package comprising the memory device.

9. The memory device of claim 6, wherein the first interface circuit and the second interface circuit are configured to process, in parallel, data transmitted to and received from the plurality of memory dies.

10. The memory device of claim 6, wherein the buffer die further comprises a mode register configured to store an interface mode parameter code indicating a single interface mode or a multi interface mode to set the single interface mode or the multi interface mode for the first interface circuit and the second interface circuit,
in the single interface mode, communication is performed with the memory controller by using the first interface circuit or the second interface circuit, and,
in the multi interface mode, communication is performed with the memory controller by using both the first interface circuit and the second interface circuit.

11. The memory device of claim 10, wherein, in the single interface mode, the first interface circuit or the second interface circuit is configured to communicate with the memory controller based on whether the first selection signal or the second selection signal is fixed to the first voltage level.

12. The memory device of claim 11, wherein the first voltage level is a voltage level of a power voltage of the memory device.

13. The memory device of claim 11, wherein the first voltage level is a voltage level of a ground voltage of the memory device.

14. The memory device of claim 10, wherein, in the multi interface mode, the first interface circuit is configured to communicate with the memory controller based on the first selection signal being fixed to the first voltage level and the second interface circuit is configured to communicate with the memory controller after the first interface circuit communicates with the memory controller based on the second selection signal being fixed to the second voltage level.

15. The memory device of claim 14, wherein the first voltage level comprises a voltage level of a power voltage of the memory device.

16. The memory device of claim 14, wherein the first voltage level comprises a voltage level of a ground voltage of the memory device.

17. A memory device comprising:
a buffer die comprising a first interface circuit and a second interface circuit configured to communicate with an external device, wherein the first interface circuit is configured to activate responsive to a first selection signal, and the second interface circuit is configured to activate responsive to a second selection signal; and
a memory die stack mounted on the buffer die and including a plurality of memory dies, wherein the plurality of memory dies are electrically connected to the first interface circuit and the second interface circuit,
wherein the first selection signal and the second selection signal are generated inside the memory device responsive to an interface selection signal received from a memory controller external to the memory device.

18. The memory device of claim 17, wherein the buffer die further comprises a decoder circuit configured to receive the interface selection signal and to generate the first selection signal and the second selection signal.

19. The memory device of claim 17, wherein the first interface circuit and the second interface circuit are configured to process, in parallel, data transmitted to and received from the plurality of memory dies.

20. The memory device of claim 17, wherein the buffer die further comprises a mode register configured to store an interface mode parameter code indicating a single interface mode or a multi interface mode to set the single interface mode or the multi interface mode for the first interface circuit and the second interface circuit,
in the single interface mode, communication is performed with the memory controller by using the first interface circuit or the second interface circuit, and,
in the multi interface mode, communication is performed with the memory controller by using both the first interface circuit and the second interface circuit.
